(19) United States
(12) Patent Application Publication
(10) Pub. No.: US 2012/0033369 A1
(43) Pub. Date: Feb. 9, 2012

(54) MOTHERBOARD WITH UNIVERSAL SERIES BUS CONNECTOR

(75) Inventors: Li-Chien Wu, Taipei City (TW); Pai-Ching Huang, Taipei City (TW)

(73) Assignee: ASUSTEK COMPUTER INC., Taipei City (TW)

(21) Appl. No.: 13/192,485

(22) Filed: Jul. 28, 2011

(30) Foreign Application Priority Data
Aug. 6, 2010 (CN) 201010247210.2

(51) Int. Cl. H05K 7/00; G06F 1/16

(52) U.S. Cl. 361/679.4; 361/760

(57) ABSTRACT

A motherboard including a bus connector and a printed circuit board (PCB) is provided. The bus connector includes a plurality of pins, and each of the pins further includes a first end and a second end. The PCB includes a plurality of contact pads. The second ends of the pins are electrically connected to the contact pads of the PCB via a surface mounted technology (SMT), respectively.

### CROSS-REFERENCE TO RELATED APPLICATION

This application claims the priority benefit of China application serial no. 201010247210.2, filed Aug. 6, 2010. The entirety of the above-mentioned patent application is hereby incorporated by reference herein and made a part of this specification.

### BACKGROUND OF THE INVENTION

1. Field of the Invention

The invention relates to a motherboard, more particularly, to a motherboard with universal series bus connectors.

2. Description of the Related Art

Universal series bus (USB) is a serial bus standard and an input/output (I/O) interface specification. It is widely used in communication products such as a personal computer and a mobile device.

The USB is initially promoted by Intel and Microsoft. It has the most important feature of supporting hot plug and plug-and-play. When a USB device is plugged into a computer system, a motherboard loads a driver of the USB device automatically. Thus, it is more convenient than peripheral component interconnect (PCI) or other buses in usage.

The data transmission speed of the USB improves continuously. The maximum transmission speed of the USB 1.1 is 12 Mbps, and the maximum transmission speed of the USB 2.0 is 480 Mbps. The maximum transmission speed of the recent USB 3.0 is improved over 4.8 Gbps. Based on the transmission speed difference, the USB 1.1 is now regarded as a low speed USB, the USB 2.0 is a high speed USB, and the USB 3.0 is regarded as a super high speed USB.

FIG. 1 is a schematic diagram showing definitions of pins of a USB 2.0 connector 10. The pins of the USB 2.0 connector 10 may be divided to a first group of connector pins 12 and a second group of connector pins 14. The first group of the connector pins 12 includes a first pin VCC, a third pin P1_D−, a fifth pin P1_D+ and a seventh pin GND. The second group of the connector pins 14 includes a second pin VCC, a fourth pin P2_D−, a sixth pin P2_D+, an eighth pin GND and a tenth pin NC.

In the first group of the connector pins 12, the first pin VCC is connected to a direct current (DC) power, the third pin P1_D− and the fifth pin P1_D+ are used for signal transmission of the USB 2.0, and the seventh pin GND is connected to the ground.

In the second group of the connector pins 14, the eighth pin GND is connected to the ground, the sixth pin P2_D+ and the fourth pin P2_D− are used for the signal transmission of the USB 2.0, the second pin VCC is connected to the DC power, and the tenth pin NC is not connected.

The outside length of the USB 2.0 connector 10 is 20.30 mm, its inside length is 17.90 mm, its width is 6.40 mm. The space between the second pin GND to the tenth pin VCC is 10.16 mm, and the interval between each two pins is 2.54 mm.

FIG. 2 is a diagram showing that a conventional USB 2.0 connector 10 is electrically connected to a printed circuit board (PCB) 20 by dual in-line package (DIP) process. Four pins 18 of the first group of the connector pins 12 in the USB 2.0 connector 10 are plugged to four weld holes 22 of the PCB 20. In the DIP, weld holes 22 are formed by drilling the PCB 20, which may result in impedance discontinuity.

Furthermore, part of each nine pins 18 of the USB 2.0 connector 10 is exposed from the bottom of the PCB 20 after plugged to the nine weld holes 22 of the PCB 20, which results in signal integrity and may generate a reflected signal. FIG. 3 is a diagram showing a transmission path of a signal sent by a USB controller (not shown) to the pins of the USB 2.0 connector 10 via a PCB trace 24 in DIP structure. When a signal A is transmitted to the weld of the pin 18 and the weld holes 22 via the trace 24 at the PCB 20, the signal A is divided to two parts. A partial signal B is transmitted to the upper part of the pin 18 above the PCB 20, and another partial signal C is transmitted to the pin 18 under the PCB 20. The partial signal B is finally transmitted to the USB 2.0 connector 10 through the upper part of the pin 18 above the PCB 20. However, the partial signal C is transmitted to the end of the pin 18 under the PCB 20. The partial signal C may be reflected to be a signal C+ and transmitted to the upper part of the pin 18 above the PCB 20 to interfere with the partial signal B.

USB connectors 10 under 2.0 specification have a signal transmission relatively slow, and thus the reflected signal C+ does not have an obvious interference on the partial signal B. However, as the USB 3.0 gradually takes place of the USB 2.0, and the transmission speed of the USB 3.0 is relatively faster than that of the USB 2.0, the interference of the reflected signal C+increases greatly.

### BRIEF SUMMARY OF THE INVENTION

A motherboard is provided which includes a bus connector and a PCB. The bus connector includes a plurality of pins, and each of the pins includes a first end and a second end. The PCB includes a plurality of contact pads. In the bus connector, the second end of the pins is electrically connected to the contact pads of the PCB via SMT.

In the motherboard, the bus connector is electrically connected to the PCB via SMT. It does not need to drill holes at the PCB, which avoids the impedance discontinuity and the reflected signal due to the exposure of the second end of the connector pins from the bottom of the PCB as in the conventional DIP.

These and other features, aspects and advantages of the present invention will become better understood with regard to the following description, appended claims, and accompanying drawings.

### BRIEF DESCRIPTION OF THE DRAWINGS

FIG. 1 is a schematic diagram showing definitions of pins of a conventional USB 2.0 connector.

FIG. 2 is a schematic diagram showing that a conventional USB 2.0 connector is electrically connected to a PCB in DIP.

FIG. 3 is a schematic diagram showing a conventional transmission path of a signal sent to pins of a conventional USB 2.0 connector via a PCB trace in DIP structure.

FIG. 4 is a diagram showing definitions of pins of a USB 3.0 connector in an embodiment of the invention.

FIG. 5 is a diagram showing that a USB 3.0 connector is connected to a PCB via SMT in an embodiment of the invention in an embodiment of the invention.

FIG. 6 is a schematic diagram showing a transmission path of a signal sent to pins of a USB 3.0 connector via a PCB trace in a SMT structure in an embodiment of the invention.

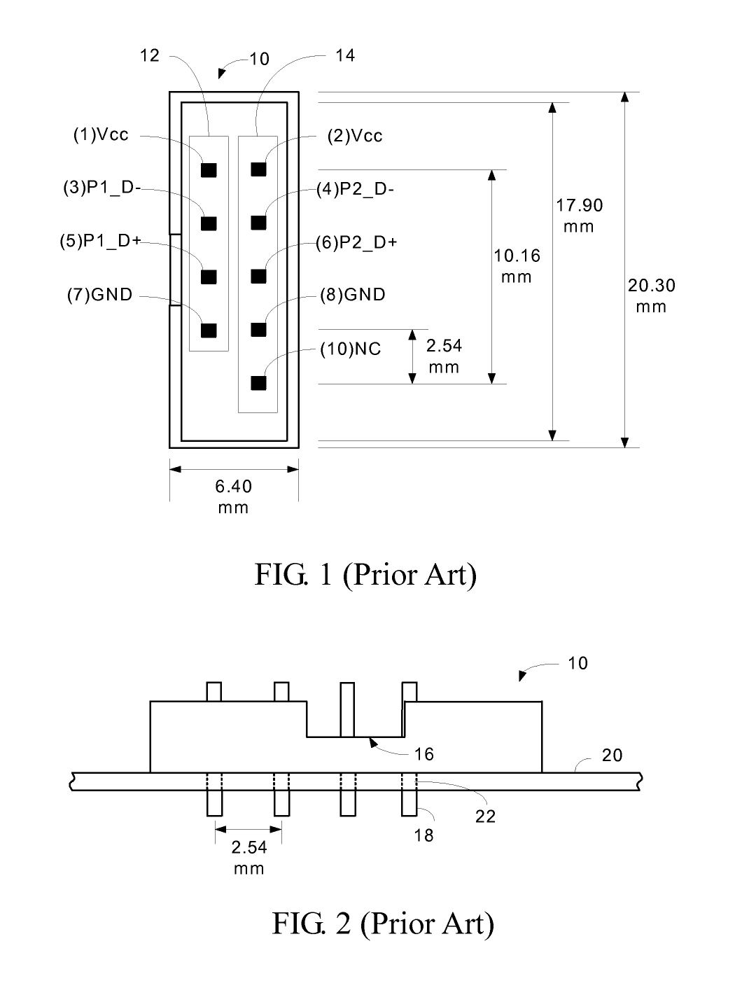

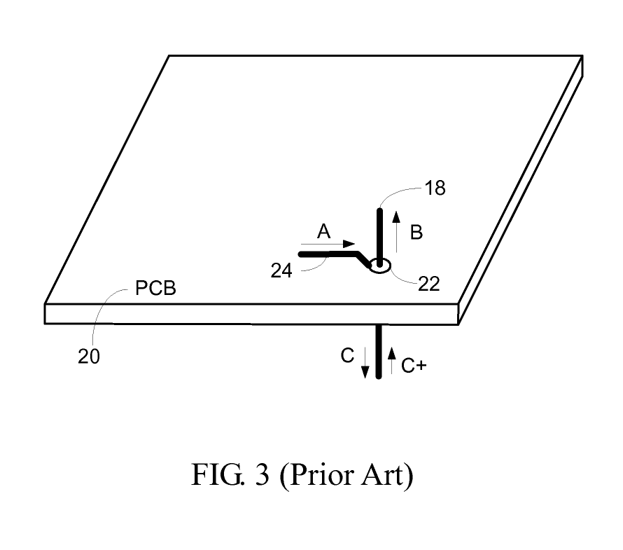

### DETAILED DESCRIPTION OF THE EMBODIMENTS

A connector is electrically connected to a PCB mainly via SMT Technology. Since it does not need to drill holes at the PCB, the signal integrity is ensured. A USB 3.0 connector is taken as an example hereinafter. Persons having ordinary skill in the art may know that other kinds of connectors connected to the circuit board via the SMT also may be within the scope of an embodiment of the invention.

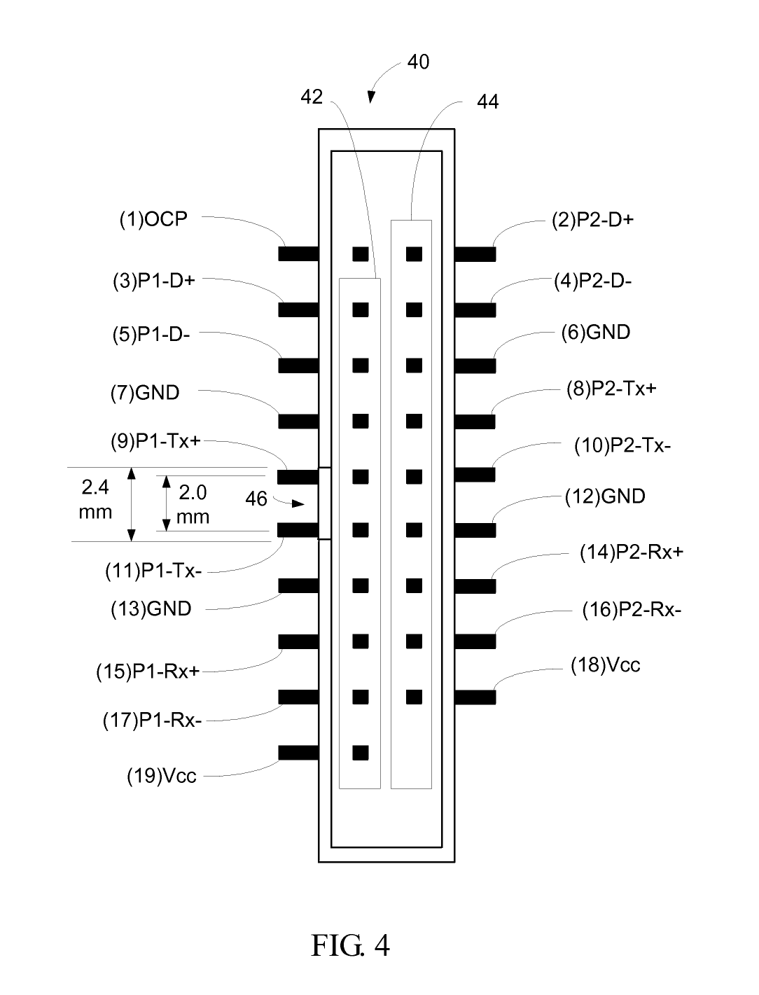

FIG. 4 is a diagram showing definitions of pins of a USB 3.0 connector 40. Pins of the USB 3.0 connector 40 may be divided into a first I/O interface connector p ins 42 and a second I/O interface connector pins 44. The first I/O interface connector pins 42 includes a third pin P1_D+, a fifth pin P1_D−, a seventh pin GND, a ninth pin P1_TX+, an eleventh pin P1_TX−, a thirteenth pin GND, a fifteenth pin P1_RX+, a seventeenth pin P1_RX− and a nineteenth pin VCC. The second I/O interface connector pins 44 includes a second pin P2_D+, a fourth pin P2_D−, a sixth pin GND, a eighth pin P2_TX+, a tenth pin P2_TX−, a twelfth pin GND, a fourteenth pin P2_RX+, a sixteenth pin P2_RX− and an eighteenth pin VCC.

In the first I/O interface connector pins 42, the third pin P1_D+ and the fifth pin P1_D− are mainly used for the signal transmission of the USB 2.0, the ninth pin P1_TX+ and the eleventh pin P1_TX− are mainly used for the signal output of the USB 3.0, the fifteenth pin P1_RX+ and the seventeenth pin P1_RX− are mainly used for the signal input of the USB 3.0, the seventh pin GND and the thirteenth pin GND are connected to the ground, and the nineteenth pin VCC is connected to the DC power.

In the second I/O interface connector pins 44, the second pin P2_D+ and the fourth pin P2_D− are mainly used for the signal transmission of the USB 2.0, the eighth pin P2_TX+ and the tenth pin P2_TX− are mainly used for the signal output of the USB 3.0, the fourteenth pin P2_RX+ and the sixteenth pin P2_RX− are mainly used for the signal input of the USB 3.0, the sixth pin GND and the twelfth pin GND are connected to the ground, and the eighteenth pin VCC is connected to the DC power. Moreover, the first pin OCP is for over-current protection.

The USB 3.0 connector 40 includes the pins defined in the USB 2.0 specification, which are the second pin P2_D+, the third pin P1_D+, the fourth pin P2_D−, and the fifth pin (P2_D−), the USB 3.0 is compatible with the USB 2.0.

Furthermore, the eighth pin P2_TX+, the ninth pin P1_TX+, the tenth pin P2_TX−, the eleventh pin P1_TX−, the fourteenth pin P2_RX+, the fifteenth pin P1_RX+, the sixteenth pin P2_RX− and the seventeenth pin P1_RX− are used for the data transmission of the USB 3.0.

The USB 3.0 connector 40 includes a fool-proof structure 46 for avoiding a wrong plugging of a USB 3.0 transmission line (not shown) and the USB 3.0 connector 40. In the first I/O interface connector pins 42 and the second I/O interface connector pins 44, the space between each adjacent pins is 2.0 mm, and the width of the fool-proof structure 46 is 2.4 mm.

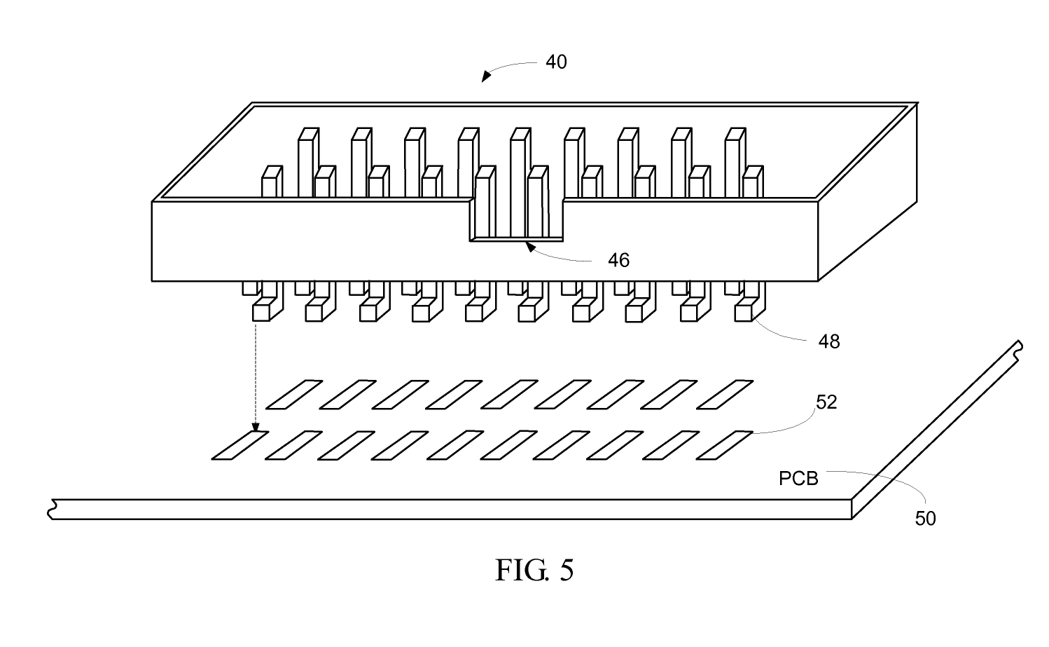

FIG. 5 is a schematic diagram showing that a USB 3.0 connector 40 is connected to a PCB 50 via SMT in an embodiment of the invention. As shown in FIG. 5, each of the pins 48 in the USB 3.0 connector 40 is L-shaped and each of the pins 48 has a first end and a second end. The first end of each of the pins 48 is connected to the contact pads 52 via SMT, and the second end of each of the pins 48 is connected to the inner part of the USB 3.0 connector 40 for electrically connecting to a transmission line plug (not shown) of the USB 3.0.

In FIG. 5, the SMT refers to that the USB 3.0 connector 40 is welded at the contact pads 52 of the PCB 50, and thus holes does not need to be drilled at the PCB 50. In detail, the contact pads 52 of the PCB 50 are coated with tin soldering paste first, and then the second ends of the pins 48 in the USB 3.0 connector 40 are placed on the specific position of the contact pads 52 with the tin soldering paste. The PCB 50 is heated until the tin soldering paste is melt. After the tin soldering paste is cooled down, the USB 3.0 connector 40 is already electrically connected to the contact pads 52 of the PCB 50. In the motherboard of the embodiment, the USB 3.0 connector 40 is electrically connected to the contact pads 52 of the PCB 50 via the SMT, so it does not need to drill holes at the PCB 50, and the impedance discontinuity of the PCB 50 in the conventional DIP is avoided.

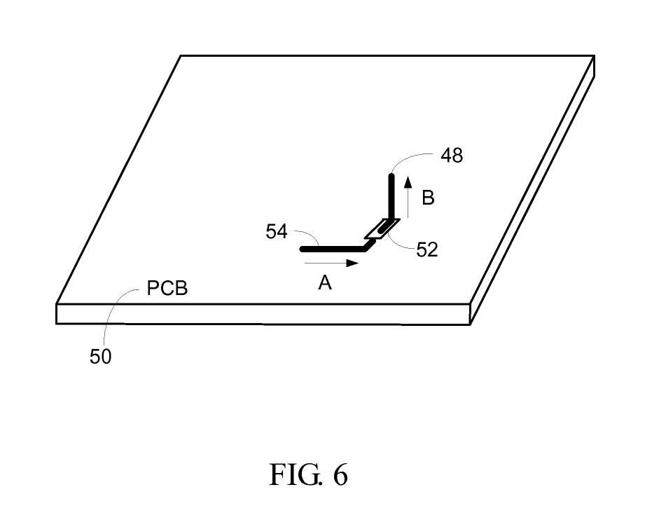

Moreover, the USB 3.0 connector 40 on the motherboard of the embodiment is electrically connected to the contact pads 52 of the PCB 50 via the SMT, the second ends of the pins in the USB 3.0 connector 40 do not pass through the PCB 50, and thus, the reflected signal is avoided. FIG. 6 is a schematic diagram showing a transmission path of a signal sent by a USB controller (now shown) to the contact pads 52 and the pins 48 of the USB 3.0 connector 40 via the trace 54 at the PCB 50 in the SMT structure. When the signal A is transmitted to the contact pads 52 via the trace 54 at the PCB 50, the signal A is transmitted to the pins 48 at the PCB 50 as the signal B completely, and the reflected signal is not generated as in the DIP.

In sum, in the motherboard of the embodiment, the USB 3.0 connector is electrically connected to the PCB via the SMT, and it does not need to drill holes at the PCB. Consequently, the impedance discontinuity of the PCB as in the conventional DIP is avoided. Moreover, in the motherboard of the embodiment, since the USB 3.0 connector is electrically connected to the PCB 50 via the SMT, the second ends of the pins in the USB 3.0 connector do not pass through the PCB, and thus the reflected signal generation is avoided.

Although the present invention has been described in considerable detail with reference to certain preferred embodiments thereof, the disclosure is not for limiting the scope of the invention. Persons having ordinary skill in the art may make various modifications and changes without departing from the scope. Therefore, the scope of the appended claims should not be limited to the description of the preferred embodiments described above.

What is claimed is:

1. A motherboard, comprising:
a bus connector including a plurality of pins, wherein each of the pins includes a first end and a second end; and
a printed circuit board (PCB) including a plurality of contact pads;
wherein the second ends of the pins of the bus connector are electrically connected to the contact pads of the PCB via a surface mounted technology (SMT).

2. The motherboard according to claim 1, wherein the pins of the bus connector includes a first input/output (I/O) interface connector pins and a second I/O interface connector pins.

3. The motherboard according to claim 2, wherein the first I/O interface connector pins includes a third pin P1_D+, a fifth pin P1_D−, a seventh pins GND, a ninth pin P1_TX+, a eleventh pin P1_TX−, a thirteenth pin GND, a fifteenth pin P1_RX+, a seventeenth pin P1_RX− and a nineteenth pin VCC.

4. The motherboard according to claim 3, wherein the third pin P1_D+ and the fifth pin P1_D− are used for signal transmission of a first I/O interface, the ninth pin P1_TX+ and the eleventh pin P1_TX− are used for signal output of a second I/O interface, the fifteenth pin P1_RX+ and the seventeenth pin P1_RX− are used for signal input of the second I/O interface, the seventh pin GND and the thirteenth pin GND are connected to ground, and the nineteenth pin VCC is connected to a direct current (DC) power.

5. The motherboard according to claim 2, wherein the second I/O interface connector pins includes a second pin P2_D+, a fourth pin P2_D−, a sixth pin GND, an eighth pin P2_TX+, a tenth pin P2_TX−, a twelfth pin GND, a fourteenth pin P2_RX+, a sixteenth pin P2_RX− and an eighteenth pin VCC.

6. The motherboard according to claim 5, wherein the second pin P2_D+ and the fourth pin P2_D− are used for signal transmission of a first I/O interface, the eighth pin P2_TX+ and the tenth pin P2_TX− are used for signal output of a second I/O interface, the fourteenth pin P2_RX+ and the sixteenth pin P2_RX− are used for signal input of the second I/O interface, the sixth pin GND and the twelfth pin GND are connected to ground, and the eighteenth pin VCC is connected to a DC power.

7. The motherboard according to claim 1, wherein the pins of the bus connector includes a first pin OCP for over-current protection.

8. The motherboard according to claim 1, wherein the bus connector includes a fool-proof structure.

9. The motherboard according to claim 1, wherein the first ends of the pins is electrically connected to a transmission line plug.
